(19) United States
(12) Patent Application Publication
(10) Pub. No.: US 2019/0084241 A1
(43) Pub. Date: Mar. 21, 2019

(54) SYSTEM AND METHODS FOR THE FABRICATION OF THREE-DIMENSIONAL OBJECTS VIA MULTISCALE MULTIPHOTON PHOTOLITHOGRAHY

(71) Applicant: Northwestern University, Evanston, IL (US)

(72) Inventors: Sridhar Krishnaswamy, Lake Forest, IL (US); Heming Wei, Evanston, IL (US)

(21) Appl. No.: 16/136,627

(22) Filed: Sep. 20, 2018

Related U.S. Application Data
(60) Provisional application No. 62/561,487, filed on Sep. 21, 2017.

(51) Int. Cl. B29C 64/393; G03F 7/20; B33Y 10/00; B33Y 30/00; B33Y 50/02; B29C 64/135; B29C 64/268

(52) U.S. Cl. CPC B29C 64/393; G03F 7/70416; B33Y 10/00; B29C 64/268; B33Y 50/02; B29C 64/135; B33Y 30/00

(57) ABSTRACT

A multiscale multiphoton photolithography system for fabricating a 3D object may comprise a support structure configured to support a light-sensitive composition from which the 3D object is to be fabricated; a microscope objective configured to focus light on the light-sensitive composition via an optical path; a first optical assembly configured to provide light of a first wavelength to the microscope objective, the first wavelength selected to induce a single photon process in the light-sensitive composition; a second optical assembly configured to provide light of a second wavelength to the microscope objective, the second wavelength selected to induce a multiphoton process in the light-sensitive composition; and a controller operably coupled to the first and second optical assemblies. The controller comprises a processor and a non-transitory computer-readable medium operably coupled to the processor, the computer-readable medium comprising instructions that, when executed by the processor, perform operations comprising illuminating, via the first optical assembly, the light-sensitive material with the first wavelength of light via the optical path to generate a first region of the 3D object via single photon photolithography; illuminating, via the second optical assembly, the light-sensitive material with the second wavelength of light via the optical path to generate a second region of the 3D object via multiphoton photolithography; and repeating steps (a) and (b) until the 3D object is complete.

### CROSS-REFERENCE TO RELATED APPLICATIONS

The present application claims priority to U.S. Provisional Patent Application No. 62/561,487 that was filed Sep. 21, 2017, the entire contents of which are hereby incorporated by reference.

### REFERENCE TO GOVERNMENT RIGHTS

This invention was made with government support under N00014-16-1-3021 awarded by the Office of Naval Research. The government has certain rights in the invention.

### BACKGROUND

Many functional devices (such as 3D printed polymer photonic devices and biosensors) require fabrication over multiple length scales that can span over several orders of magnitude. Unfortunately, existing 3D fabrication systems generally achieve fabrication at a single scale, which is dictated by the finest scale needed for the entire device. Fabricating multiscale devices voxel by voxel at a single highest resolution scale is impractical within reasonable time scales.

### SUMMARY

Provided are multiscale multiphoton photolithography systems and methods for fabricating three-dimensional (3D) objects.

In one aspect, a multiscale multiphoton photolithography system for fabricating a 3D object is provided. In an embodiment, the system comprises a support structure configured to support a light-sensitive composition from which the 3D object is to be fabricated; a microscope objective configured to focus light on the light-sensitive composition via an optical path; a first optical assembly configured to provide light of a first wavelength to the microscope objective, the first wavelength selected to induce a single photon process in the light-sensitive composition; a second optical assembly configured to provide light of a second wavelength to the microscope objective, the second wavelength selected to induce a multiphoton process in the light-sensitive composition; and a controller operably coupled to the first and second optical assemblies. The controller comprises a processor and a non-transitory computer-readable medium operably coupled to the processor, the computer-readable medium comprising instructions that, when executed by the processor, perform operations comprising illuminating, via the first optical assembly, the light-sensitive material with the first wavelength of light via the optical path to generate a first region of the 3D object via single photon photolithography; illuminating, via the second optical assembly, the light-sensitive material with the second wavelength of light via the optical path to generate a second region of the 3D object via multiphoton photolithography; and repeating steps (a) and (b) until the 3D object is complete.

In another aspect, a controller for controlling the operations of a multiscale multiphoton photolithography system is provided. In an embodiment, the controller comprises a processor; and a non-transitory computer-readable medium operably coupled to the processor, the computer-readable medium comprising instructions that, when executed by the processor, perform operations comprising illuminating, via a first optical assembly of the system, a light-sensitive material from which a 3D object is to be fabricated with a first wavelength of light selected to induce a single photon process in the light-sensitive composition to generate a first region of the 3D object via single photon photolithography; illuminating, via a second optical assembly of the system, the light-sensitive material with a second wavelength of light selected to induce a multiphoton process in the light-sensitive composition to generate a second region of the 3D object via multiphoton photolithography; and repeating steps (a) and (b) until the 3D object is complete.

In another aspect, a non-transitory computer-readable medium is provided. In an embodiment, the non-transitory computer-readable medium comprises computer-readable instructions therein that, when executed by a processor, cause a controller configured to control the operations of a multiscale multiphoton photolithography system to: illuminate, via a first optical assembly of the system, a light-sensitive material from which a 3D object is to be fabricated with a first wavelength of light selected to induce a single photon process in the light-sensitive composition to generate a first region of the 3D object via single photon photolithography; illuminate, via a second optical assembly of the system, the light-sensitive material with a second wavelength of light selected to induce a multiphoton process in the light-sensitive composition to generate a second region of the 3D object via multiphoton photolithography; and repeat steps (a) and (b) until the 3D object is complete.

In another aspect, a method for fabricating a 3D object is provided. In an embodiment, the method comprises illuminating, via a first optical assembly, a light-sensitive material from which the 3D object is to be fabricated with a first wavelength of light selected to induce a single photon process in the light-sensitive composition to generate a first region of the 3D object via single photon photolithography; illuminating, via a second optical assembly, the light-sensitive material with a second wavelength of light selected to induce a multiphoton process in the light-sensitive composition to generate a second region of the 3D object via multiphoton photolithography, wherein the illuminating steps (a) and (b) occur along the same optical path of a multiscale multiphoton photolithography system; and repeating steps (a) and (b) until the 3D object is complete.

Other principal features and advantages of the disclosure will become apparent to those skilled in the art upon review of the following drawings, the detailed description, and the appended claims.

### BRIEF DESCRIPTION OF THE DRAWINGS

Illustrative embodiments of the disclosure will hereafter be described with reference to the accompanying drawings.

FIG. 1 depicts a multiscale multiphoton photolithography system for fabricating 3D objects according to an illustrative embodiment.

FIG. 2 depicts a flow chart associated with the system of FIG. 1 according to an illustrative embodiment.

FIG. 3 depicts a controller that may be included in the system of FIG. 1 according to an illustrative embodiment.

FIG. 4A depicts operations which may be performed by an application of the controller of FIG. 3 to generate photolithography data for fabricating the 3D object.

FIG. 4B depicts additional operations associated with generating the photolithography data.

FIG. 5 depicts operations which may be performed by the application of the controller of FIG. 3 to control components of the system of FIG. 1 based on the photolithography data.

FIG. 6 is a scanning electron microscope (SEM) image of a multiscale 3D object (a sub-waveguide connector) fabricated using the system and methods described herein.

FIG. 7 is a SEM image of a multiscale 3D object (a micro-fence with bulk supporter) fabricated using the system and methods described herein.

FIG. 8 is a SEM image of a multiscale 3D object (a micro holder) fabricated using the system and methods described herein.

FIG. 9 is a SEM image of a multiscale 3D object (micro half-sphere lenses) fabricated using the system and methods described herein.

FIG. 10 is a SEM image of a multiscale 3D object (a curve waveguide connector) fabricated using the system and methods described herein.

FIG. 11 is a SEM image of a multiscale 3D object (a tapered waveguide with micro-ring) fabricated using the system and methods described herein.

### DETAILED DESCRIPTION

Provided are multiscale multiphoton photolithography systems and methods for fabricating three-dimensional (3D) objects. The system and methods integrate single and multiphoton photolithography to fabricate 3D objects at multiple resolution scales (e.g., high and low resolution) simultaneously at reasonable timescales.

The 3D objects to be fabricated may be those having multiscale structural features, i.e., a structural feature(s) characterized by one length scale and another structural feature(s) characterized by another, different length scale. A structural feature characterized by the smaller length scale may be referred to as a “high resolution feature” and a structural feature characterized by the larger length scale may be referred to as a “low resolution feature.” The specific magnitude of each of the length scales is not critical. In embodiments, high resolution features may include structural features having length scales of 1 μm or less, 500 nm or less, 100 nm or less, in the range of from about 1 nm to 1 μm, etc. In embodiments, low resolution features may include structural features having length scales of greater than 1 μm, greater than 10 μm, greater than 50 μm, in the range of from about 1 μm to about 100 μm, etc. The 3D object may have additional structural features characterized by yet another, different length scale, e.g., a “medium resolution feature” characterized by a length scale between the length scales of the low and high resolution features. 3D objects having multiscale structural features may be referred to as “multiscale 3D objects.”

In general, a multiscale multiphoton photolithography system may include a support structure configured to support a substrate (e.g., a transparent wafer or microscope slide) on which the 3D object is to be fabricated. The support structure may include a multi-axis stage (e.g., a xyz stage configured to move in three dimensions) and/or a tilt platform. For small 3D objects, a single-axis stage may be used to control the height of the 3D object. For larger 3D structures, a xy stage may be used for stitching.

The supported substrate may include a light-sensitive composition (e.g., coated on a surface of the substrate) from which the 3D object is to be composed. However, a tank comprising a tank plate formed of an oxygen permeable thin film may be used to contain the light-sensitive composition and to accommodate the substrate upon immersion into the light-sensitive composition. Such an embodiment may be used for carrying out a continuous liquid interface production (CLIP) process. The light-sensitive composition comprises a photoresist material. A variety of photoresist materials may be used, including negative and positive photoresist materials. Depending upon the desired composition of the 3D object, the light-sensitive composition may include other materials, e.g., glass, ceramic, metallic, semiconductor particles, e.g., microparticles, nanoparticles.

The system may include a microscope objective configured to focus light on/in the light-sensitive composition to induce both single photon processes and multiphoton (e.g., two-photon) processes (e.g., polymerization reactions) therein. Such processes may be referred to as single photon photolithography (1PP) and for two photon processes, two photon photolithography (2PP). The system may include a first optical assembly configured to provide light of a first wavelength to the microscope objective, the first wavelength selected to induce a single photon process in the light-sensitive composition. Similarly, the system may include a second optical assembly configured to provide light of a second wavelength to the microscope objective, the second wavelength selected to induce a multiphoton process in the light-sensitive composition. Since both the first and second wavelengths of light pass through the same microscope objective along the same optical path therein, the system provides for collocated illumination. In this way, fabrication of the 3D object via single and multiphoton photolithography, induced by the first and second wavelengths of light, respectively, can occur simultaneously. However, sequential illumination may also be used by turning on/off the first and second wavelengths of light as further described below. Illumination using the first and second wavelengths of light via the same optical path of a multiscale multiphoton photolithography system (e.g., the same microscope objective) distinguishes methods and systems involving separate photolithography systems. In such separate photolithography systems, separate optical paths are defined in each individual photolithography system (e.g., two separate microscope objectives) and the optical assemblies of the separate photolithography systems are not in optical and/or electrical communication with one another as is true of the disclosed system and methods.

The first and second wavelengths of light are not particularly limited, provided they are capable of inducing the single photon and the multiphoton processes, respectively, in the selected light-sensitive composition. The first wavelength of light may be in the ultraviolet portion of the electromagnetic spectrum and the second wavelength of light may be in the visible or near-infrared portion of the electromagnetic spectrum. Similarly, the first and second optical assemblies are not particularly limited, but may include components for generating the light (light sources), optical components for directing the light (dichroic mirrors, lenses, etc.), as well as electrical components associated with the light sources and optical components. Optical and electrical components may be shared between the first and second optical assemblies.

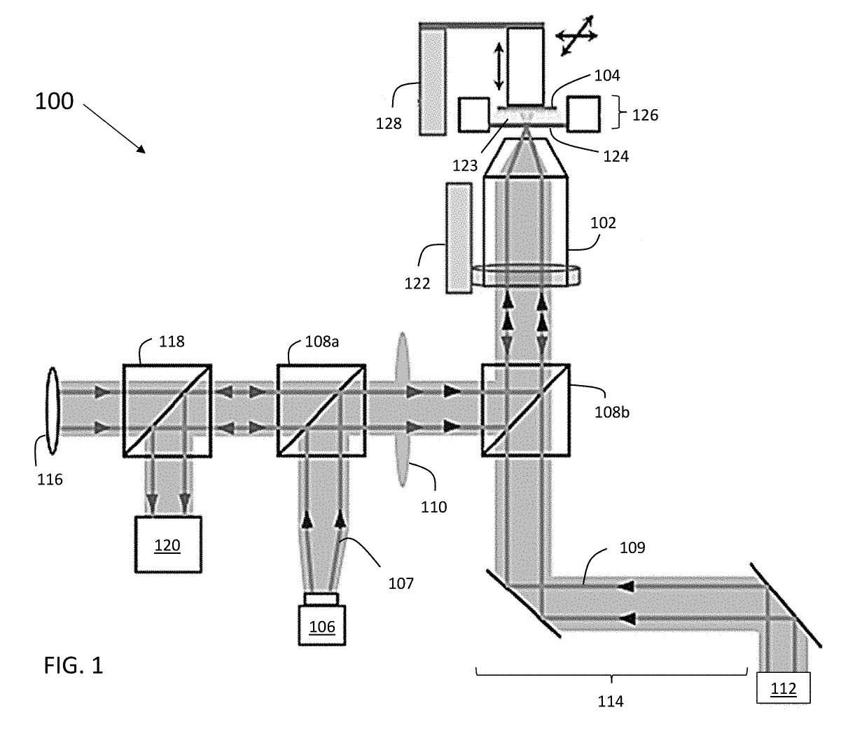

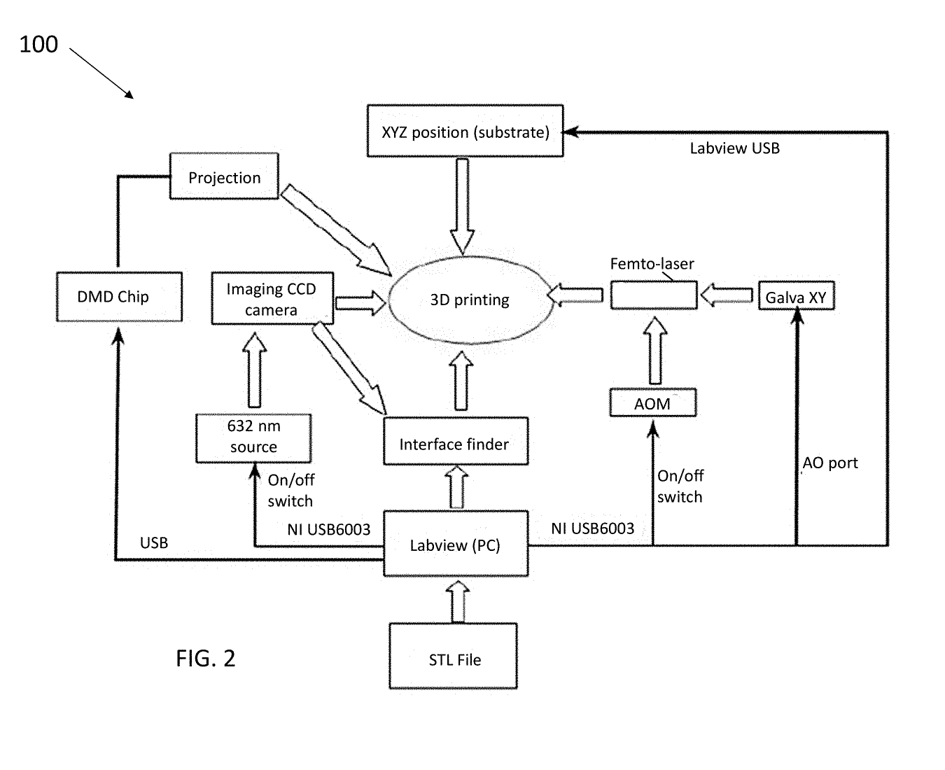

An illustrative embodiment of a multiscale multiphoton photolithography system 100 is shown in FIG. 1. A flow chart view associated with the system 100 of FIG. 1 is shown in FIG. 2. However, the present disclosure encompasses embodiments of systems which include additional or fewer components as compared to those shown in FIGS. 1 and 2.

As shown in FIG. 1, a microscope objective 102 (e.g., a 10x or 20x objective) of the system 100 focuses light to a field of view (FOV) of about 200×200 μm on a substrate 104, positionable via an xyz stage 128. A first optical assembly comprises, e.g., a digital micromirror device (e.g., DLP4500_{EVM}) 106 configured to generate light of the first wavelength 107 (e.g., 405 nm) as an adjustable, two-dimensional pattern. The dichroic mirrors 108a, 108b and the tube lens 110 direct the patterned light to the microscope objective 102. (Also see “DMD Chip” and “Projection” in FIG. 2.) A second optical assembly comprises, e.g., a femtosecond laser device 112 configured to generate light of the second wavelength 109 (e.g., 780 nm). A two-dimensional (2D) scanning galvo mirror system 114 directs this light 109 to the microscope objective 102 as well as allows the focused light to be raster scanned in two dimensions along the substrate 104. (Also see “Femto-laser” and “GalvaXY” in FIG. 2.) The microscope objective 102 focuses the patterned light 107 of the first wavelength to induce single photon processes within the light-sensitive material for low resolution features of the 3D object (e.g., structural features having length scales of about 1 μm or greater), thereby achieving single photon photolithography. Simultaneously, the microscope objective 102 focuses the second wavelength of light 109 to a single focal spot to induce two-photon processes within the light-sensitive material for high resolution features of the 3D object (e.g., structural features having length scales in the sub-diffraction limit, i.e., about 100 nm or less), thereby achieving multiphoton photolithography. (Also see “3D printing” in FIG. 2.) Thus, the first and second wavelengths of light 107, 109 travel the same optical path through the same microscope objective 102. The focal spot of the second wavelength of light 109 may be raster scanned as described above.

The system 100 may include a variety of other components, assemblies, and/or devices. By way of illustration, as shown in FIG. 1, a third light source 116 (e.g., a light emitting device (LED) such as a low-coherence red (633 nm) LED), a beam splitter 118 and a photodetector 120 (e.g., CCD camera) may be included to image the substrate during fabrication of the 3D object. The third light source 116 and a z-axis stage 122 mounted to the microscope objective 102 may be included to facilitate alignment along the z-axis. By scanning the microscope objective 102 in the z-direction and monitoring the interference fringe from the third light source 116, it is possible to identify the z-location accurately. (Also see “632 nm source,” “Imaging CCD camera” and “Interface finder” in FIG. 2.) This is useful when implementing the CLIP process in order to find the interface between a light-sensitive material 123 and an oxygen permeable thin film 124 of a tank 126. An Acousto-Optic Modulator (AOM) system may be included as an optical switch to turn the light of the second wavelength from the femtosecond laser device 112 on/off (see FIG. 2). For system mounting, a tilt and rotation stage may be used to correct the substrate position and to adjust the position of the fabricated 3D objects by other methods (phase mask, etc.).

Any of the disclosed systems may include a controller configured to control one or more components of the system. The controller may also be configured to generate photolithography data to be used during fabrication of the 3D object. The controller may be integrated into the system as part of a single device or its functionality may be distributed across one or more devices that are connected to other system components directly or through a network that may be wired or wireless. A database (not shown), a data repository for the system, may also be included and operably coupled to the controller.

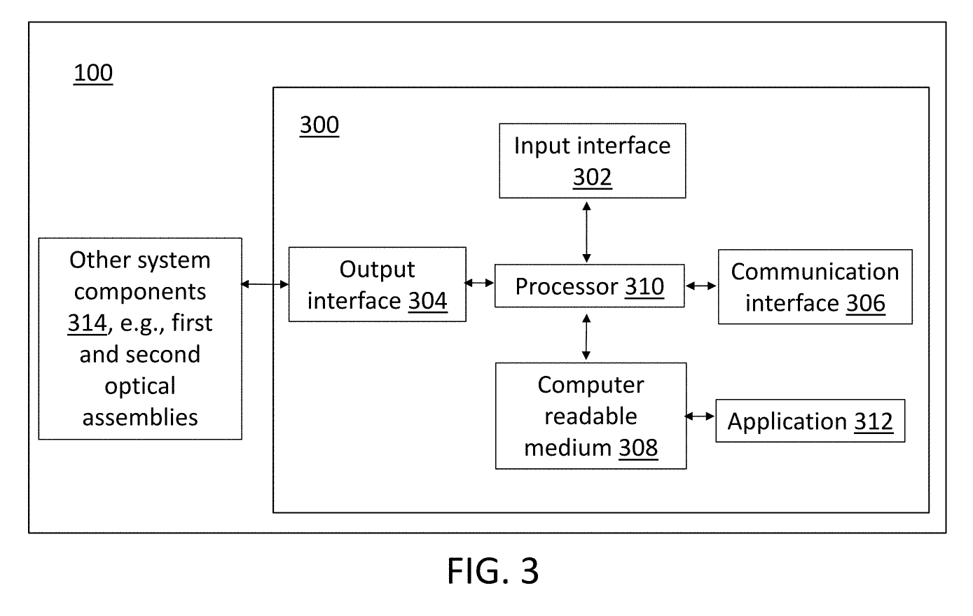

As shown in the illustrative embodiment of FIG. 3, a controller 300 which may be included in any of the disclosed systems, including system 100, may include an input interface 302, an output interface 304, a communication interface 306, a computer-readable medium 308, a processor 310, and an application 312. The controller 300 may be a computer of any form factor including an electrical circuit board.

The input interface 302 provides an interface for receiving information into the controller 300. Input interface 302 may interface with various input technologies including, e.g., a keyboard, a display, a mouse, a keypad, etc. to allow a user to enter information into the controller 300 or to make selections presented in a user interface displayed on the display. Input interface 302 further may provide the electrical connections that provide connectivity between the controller 300 and other components of the system 100.

The output interface 304 provides an interface for outputting information from the controller 300. For example, output interface 304 may interface with various output technologies including, e.g., the display or a printer for outputting information for review by the user. Output interface 304 may further provide an interface for outputting information to other components 314 of the system 100.

The communication interface 306 provides an interface for receiving and transmitting data between devices using various protocols, transmission technologies, and media. Communication interface 306 may support communication using various transmission media that may be wired or wireless. Data and messages may be transferred between the controller 300, the database, other components of the system 100 and/or other external devices using communication interface 306.

The computer-readable medium 308 is an electronic holding place or storage for information so that the information can be accessed by the processor 310 of the controller 300. Computer-readable medium 308 can include any type of random access memory (RAM), any type of read only memory (ROM), any type of flash memory, etc. such as magnetic storage devices, optical disks, smart cards, flash memory devices, etc.

The processor 310 executes instructions. The instructions may be carried out by a special purpose computer, logic circuits, or hardware circuits. Thus, the processor 310 may be implemented in hardware, firmware, or any combination of these methods and/or in combination with software. The term “execution” is the process of running an application 312 or the carrying out of the operation called for by an instruction. The instructions may be written using one or more programming language, scripting language, assembly language, etc. Processor 310 executes an instruction, meaning that it performs/controls the operations called for by that instruction. Processor 310 operably couples with the input interface 302, with the output interface 304, with the computer-readable medium 308, and with the communication interface 306 to receive, to send, and to process information. Processor 310 may retrieve a set of instructions from a permanent memory device and copy the instructions in an executable form to a temporary memory device that is generally some form of RAM.

The application 312 performs operations associated with controlling other components of the system 100. Some of these operations may include generating photolithography data to be used during fabrication of the 3D object. Other of these operations may include controlling components of the system 100 based on the photolithography data. Some or all of the operations described in the present disclosure may be controlled by instructions embodied in the application 312. The operations may be implemented using hardware, firmware, software, or any combination of these methods. With reference to the illustrative embodiment of FIG. 3, the application 312 is implemented in software (comprised of computer-readable and/or computer-executable instructions) stored in the computer-readable medium 308 and accessible by the processer for execution of the instructions that embody the operations of application 312. The application 312 may be written using one or more programming languages, assembly languages, scripting languages, etc.

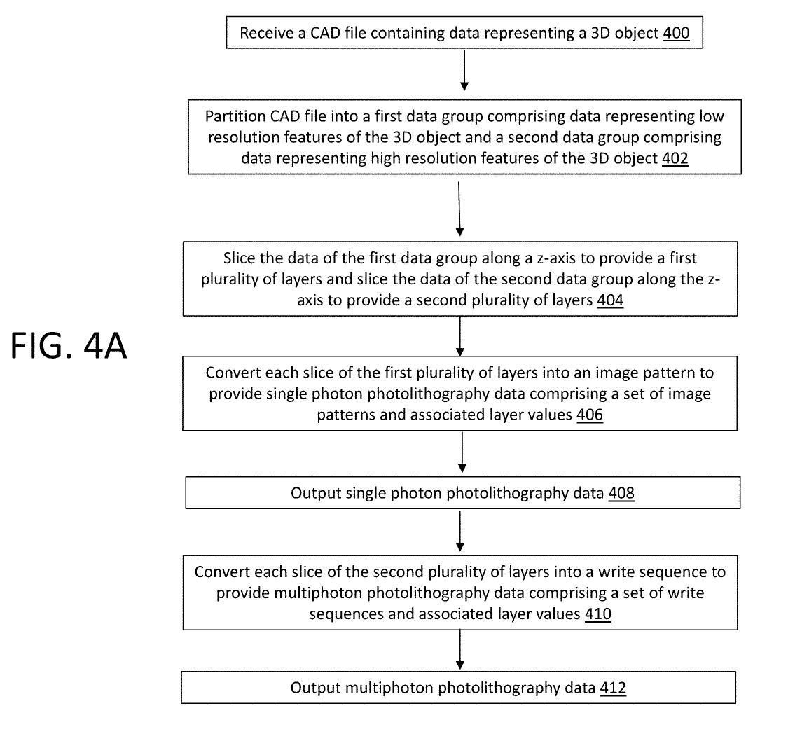

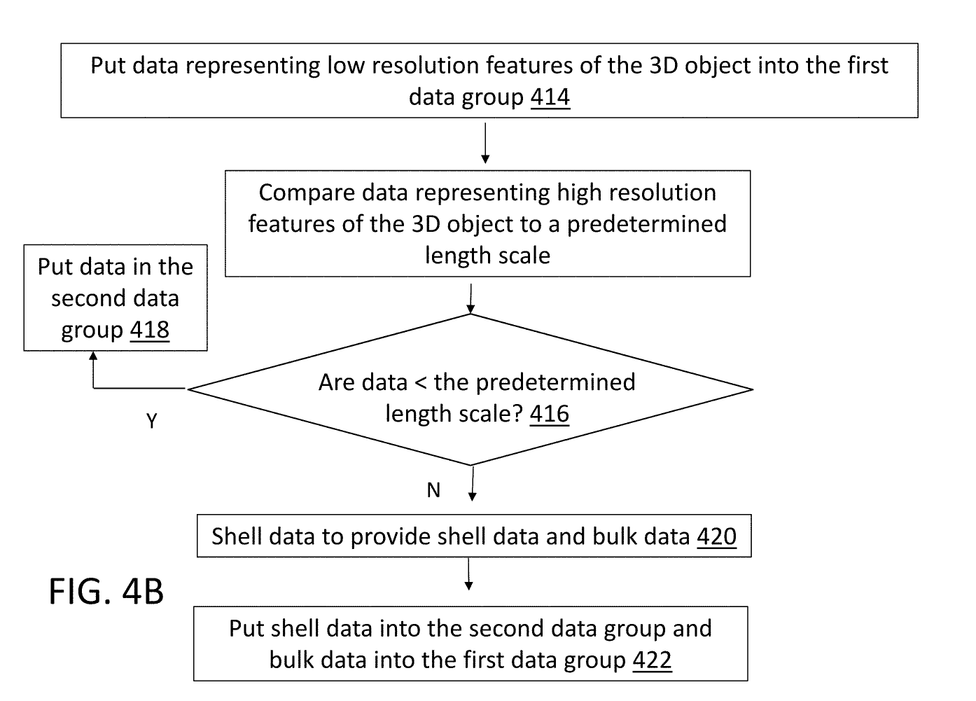

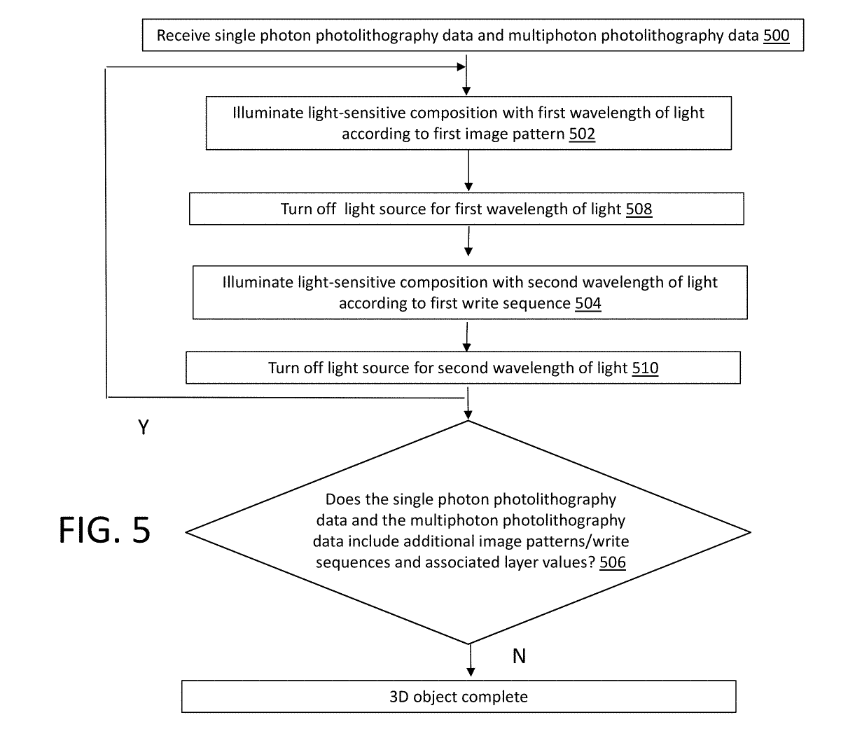

With reference to FIGS. 4A, 4B and 5, operations which may be associated with the application 312 are described according to illustrative embodiments. FIGS. 4A and 4B relate to operations for generating photolithography data. FIG. 5 relates to operations for controlling components of any of the disclosed systems, including the system 100, based on photolithography data. In these figures, additional or fewer operations may be performed depending on the embodiment. Also, the order of the operations is not intended to be limiting. Thus, although some of the operational flows are presented in sequence, the various operations may be performed in various repetitions, concurrently, and/or in other orders than those that are illustrated.

With reference to FIG. 4A, in a first operation 400, a CAD file containing data representing a 3D object (e.g., a multiscale 3D object) to be fabricated is received for processing by the processor 310. (Also see “STL File” and “Labview (PC)” in FIG. 2.) The data of the CAD file includes data representing the various structural features of the 3D object, e.g., high resolution features and low resolution features. The CAD file may be input by a user via the input interface 302 or received by reading from the computer-readable medium 308 or the database (e.g., via the communication interface 306).

In a second operation 402, data of the CAD file is partitioned into two data groups including a first data group comprising data representing the structural features of the 3D object to be fabricated using lower resolution single photon photolithography and a second group comprising data representing the structural features to be fabricated using higher resolution multiphoton photolithography.

As shown in FIG. 4B, partitioning the data of the CAD file into the first and second data groups may include a first operation 414 of putting data representing the low resolution features into the first data group. Partitioning may further include assessing the data representing the high resolution features prior to partitioning. Specifically, in an operation 416, a determination is made as to whether data representing the high resolution features are less than a predetermined length scale (e.g., less than 100 nm). If the determination is yes, in an operation 418, the data are put into the second data group. If the determination is no, in an operation 420, the remaining data is shelled. Shelling may be carried out using commercially available software. In an operation 422, the shell data are put into the second data group and the data associated with the remainder (i.e., bulk data) are put into the first data group. This approach ensures reproduction of high resolution surface features of the 3D object while retaining faster throughput associated with single photon photolithography.

Returning to FIG. 4A, in a third operation 404, the data of the first data group are sliced along the z-axis (see FIG. 1) to provide a first plurality of layers and the data of the second data group are sliced along the z-axis to provide a second plurality of layers. Slicing may be carried out using commercially available software. Prior to slicing, the data of the first and second data groups may be represented as voxels.

In a fourth operation 406, each slice of the first plurality of layers of the first data group is converted into an image pattern (e.g., a 24 bit image pattern). Each image pattern corresponds to a pattern of light for forming the low resolution features of a discrete layer of the 3D object via single photon photolithography. The plurality of image patterns may be referred to as single photon photolithography data, the data comprising a set of image patterns and associated layer values (i.e., 1^{st} layer, 2^{nd} layer, . . . , n^{th} layer).

In a fifth operation 408, the single photon photolithography data is output to the first optical assembly configured to provide the first wavelength of light for single photon photolithography (see FIGS. 1 and 3). As described further below, the outputted data may be used in controlling operation of various components of the assembly during fabrication of the 3D object.

In sixth operation 410, each slice of the second plurality of layers of the second data group is converted to a write sequence. Each write sequence corresponds to a raster scan of light for forming the high resolution features of a discrete layer of the 3D object via multiphoton photolithography. The plurality of write sequences may be referred to as multiphoton photolithography data, the data comprising a set of write sequences and associated layer values.

In a seventh operation 412, the multiphoton photolithography data is output to the second optical assembly configured to provide the second wavelength of light for multiphoton photolithography (see FIGS. 1 and 3). As described further below, the data may be used in controlling operation of various components of the assembly during fabrication of the 3D object.

As noted above, the controller 300 may be used to control the first and second optical assemblies (or components thereof) based on the photolithography data in order to fabricate the 3D object. This photolithography data may be generated by the controller 300 as described above, or alternatively, by an external device operably coupled to the controller 300.

With reference to FIG. 5, operations for fabricating a 3D object based on the photolithography data are shown according to an illustrative embodiment. In a first operation 500, single photon photolithography data comprising a set of image patterns and associated layer values is received by the first optical assembly and multiphoton photolithography data comprising a set of write sequences and associated layer values is received by the second optical assembly. In a second operation 502, the light-sensitive composition is illuminated with the first wavelength of light according to the first image pattern. As described above, this illumination step forms the low resolution features within a first layer of the 3D object via single photon photolithography. In a third operation 504, the light-sensitive composition is illuminated with the second wavelength of light according to the first write sequence. This illumination step forms the high resolution features within the first layer of the 3D object via multiphoton photolithography. In a fourth operation 506, a determination is made whether the photolithography data include any additional image patterns/write sequences and associated layer values. If the determination is yes, the second and third operations may be repeated. When the determination is no, the fabrication of the 3D object is complete. After fabrication, the 3D object may be developed per standard photolithography processes. Operations for turning off the light source for the first wavelength of light during illumination with the second wavelength of light (and vice versa) may be included (see operations 508 and 510). These operations provide for sequential illumination as opposed to simultaneous illumination. Either type of illumination may be used. Operations for moving the substrate along the z-axis depending upon the layer value may be included.

It is noted that devices including the processor 310, the computer-readable medium 308 operably coupled to the processor 310, the computer-readable medium 308 having computer-readable instructions stored thereon that, when executed by the processor 310, cause the device to perform any of the operations described above (or various combinations thereof) are encompassed by the disclosure. The computer-readable medium 308 is similarly encompassed.

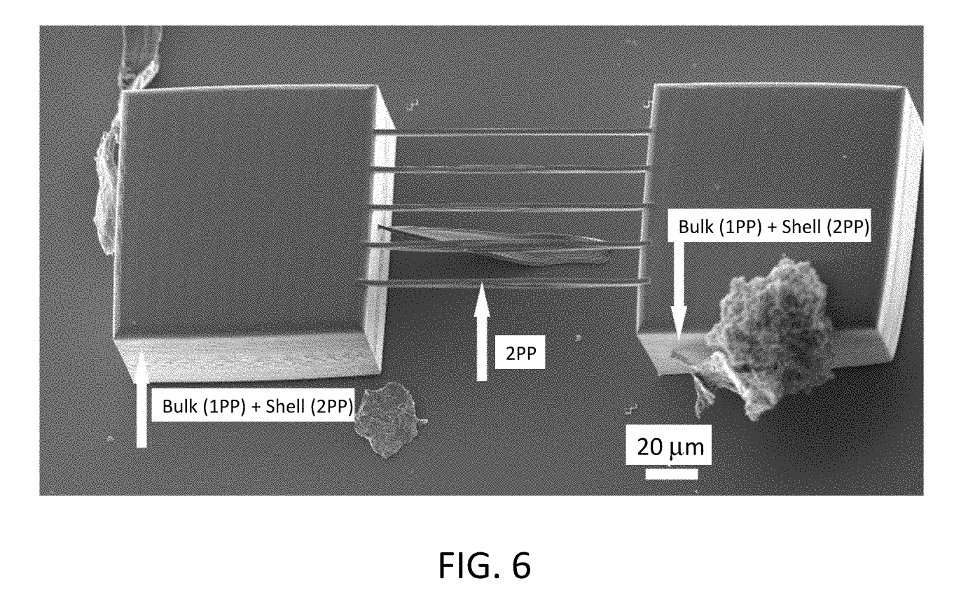

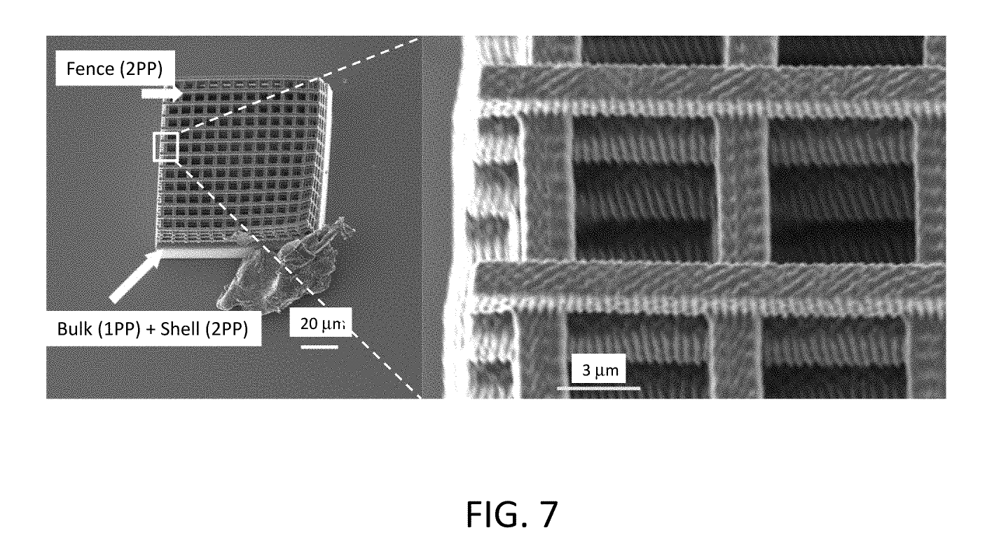

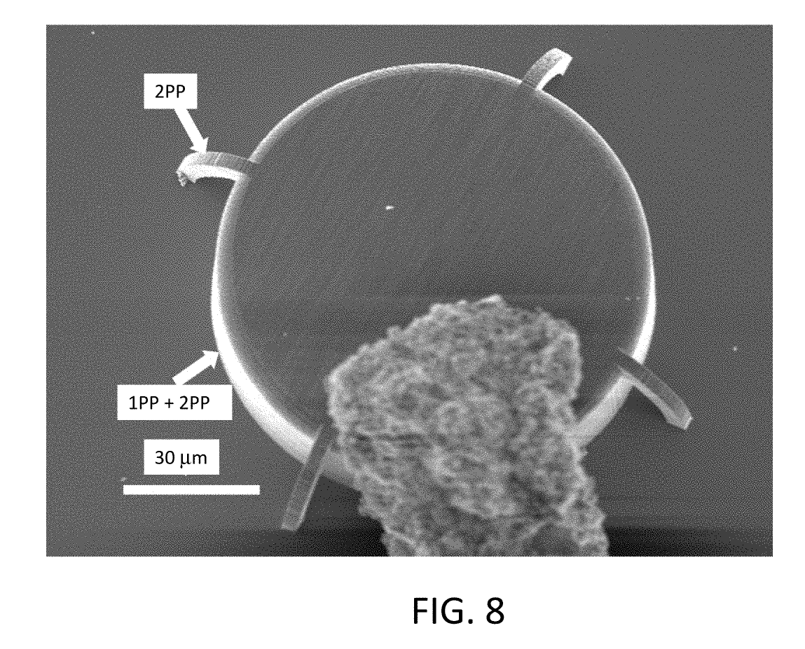

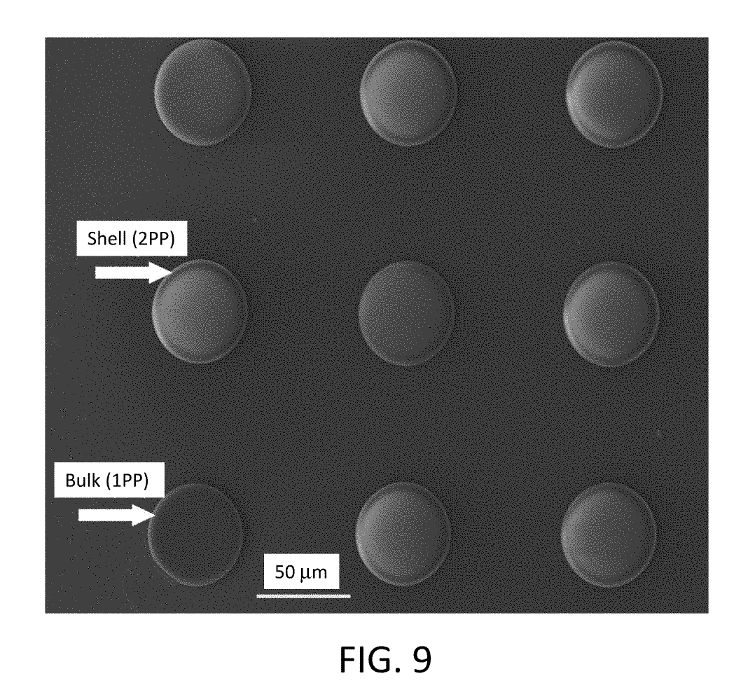

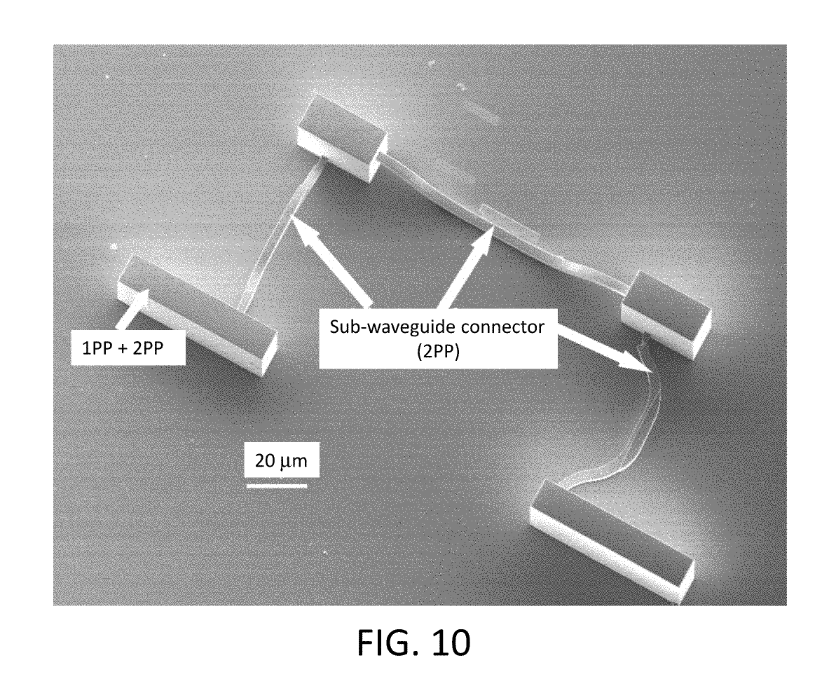

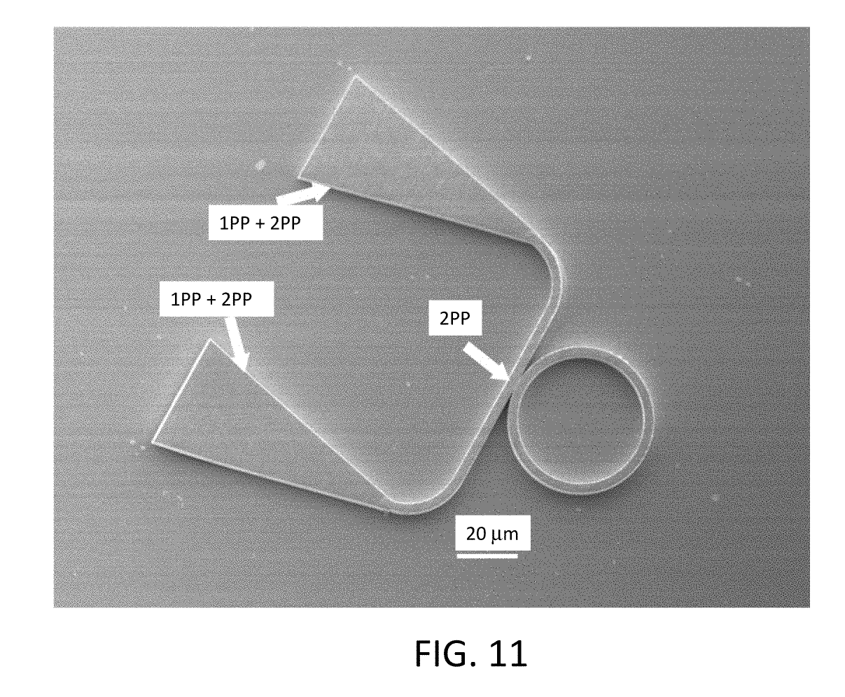

FIGS. 6-11 show SEM images of multiscale 3D objects fabricated using system and methods described above. The multiscale 3D objects include a sub-waveguide connector (FIG. 6), a micro-fence with bulk supporter (FIG. 7), a micro holder (FIG. 8), a micro half-sphere lens (FIG. 9), a curve waveguide connector (FIG. 10), and a tapered waveguide with micro-ring (FIG. 11). In these figures, “1PP” refers to those portions of the 3D objects formed via single photon photolithography and “2PP” refers to those portions of the 3D objects formed via two photon photolithography. Also, in these figures, “bulk” refers to bulk data representing the 3D object and “shell” refers to “shell data” representing the 3D object.

The systems and methods described herein may be used to fabricate the following types of structures: polymer photonic sensors (ultrahigh frequency ultrasound detection, chemical sensing); optofluidic and microfluidic sensors for gas and liquid sensing; polymer biosensors; biomedical devices; integrated optical circuits; and active/functional lasers. This list is not intended to be limiting.

Advantages of at least some embodiments of the systems and methods described herein include at least an order of magnitude decrease in fabrication time for multiscale 3D objects. As noted above, conventional systems and methods for fabricating 3D objects either sacrifice resolution (e.g., by using only single photon photolithography to reduce fabrication time) or fabrication time (e.g., by using only two photon photolithography to improve resolution). Sequential methods in which certain low resolution features are formed using a single photon photolithography system and certain high resolution features are formed using a separate, multiphoton photolithography system is not viable due to registration mismatches as well as post-development shrinkage which leads to undesirable residual stresses in the fabricated 3D object.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the disclosure has been presented for purposes of illustration and of description. It is not intended to be exhaustive or to limit the disclosure to the precise form disclosed, and modifications and variations are possible in light of the above teachings or may be acquired from practice of the disclosure. The embodiments were chosen and described in order to explain the principles of the disclosure and as practical applications of the disclosure to enable one skilled in the art to utilize the disclosure in various embodiments and with various modifications as suited to the particular use contemplated. It is intended that the scope of the disclosure be defined by the claims appended hereto and their equivalents.

What is claimed is:

1. A multiscale multiphoton photolithography system for fabricating a 3D object, the system comprising:
a support structure configured to support a light-sensitive composition from which the 3D object is to be fabricated;
a microscope objective configured to focus light on the light-sensitive composition via an optical path;
a first optical assembly configured to provide light of a first wavelength to the microscope objective, the first wavelength selected to induce a single photon process in the light-sensitive composition;
a second optical assembly configured to provide light of a second wavelength to the microscope objective, the second wavelength selected to induce a multiphoton process in the light-sensitive composition; and
a controller operably coupled to the first and second optical assemblies, the controller comprising a processor and a non-transitory computer-readable medium operably coupled to the processor, the computer-readable medium comprising instructions that, when executed by the processor, perform operations comprising:
(a) illuminating, via the first optical assembly, the light-sensitive material with the first wavelength of light via the optical path to generate a first region of the 3D object via single photon photolithography;
(b) illuminating, via the second optical assembly, the light-sensitive material with the second wavelength of light via the optical path to generate a second region of the 3D object via multiphoton photolithography; and
(c) repeating steps (a) and (b) until the 3D object is complete.

2. The system of claim 1, wherein the first optical assembly comprises a first light source configured to generate the first wavelength of light, the second optical assembly comprises a second light source configured to generate the second wavelength of light, or both.

3. The system of claim 2, wherein the first light source is provided by a digital micromirror device and the second light source is provided by a laser.

4. The system of claim 1, wherein the step of illuminating with the first wavelength of light occurs according to a first image pattern from single photon photolithography data received by the processor, the single photon photolithography data comprising a set of image patterns and associated layer values, wherein the first image pattern is one of the set,
and wherein the step of illuminating with the second wavelength of light occurs according to a first write sequence from multiphoton photolithography data received by the processor, the multiphoton photography data comprising a set of write sequences and associated layer values, wherein the first write sequence is one of the set.

5. The system of claim 4, the non-transitory computer-readable medium further comprising instructions that, when executed by the processor, cause the controller to generate the single photon photolithography data and the multiphoton photolithography data.

6. The system of claim 5, the non-transitory computer-readable medium further comprising instructions that, when executed by the processor, cause the controller to generate the single photon photolithography data and the multiphoton photolithography data by operations comprising:
partitioning a CAD file comprising data representing the 3D object to be fabricated into a first data group comprising data representing low resolution features of the 3D object and a second data group comprising data representing high resolution features of the 3D object;
slicing the first data group along a z-axis of the 3D object to provide a first plurality of layers and slicing the second data group along the z-axis to provide a second plurality of layers;
converting each layer of the first plurality of layers to an image pattern, thereby providing the single photon photolithography data comprising the set of image patterns and associated layer values and converting each layer of the second plurality of layers to a write sequence, thereby providing the multiphoton photolithography data comprising the set of write sequences and associated layer values; and
outputting the single photon photolithography data to the first optical assembly and outputting the multiphoton photolithography data to the second optical assembly.

7. The system of claim 6, the non-transitory computer-readable medium further comprising instructions that, when executed by the processor, cause the controller to partition the CAD file by operations comprising:
putting data representing the low resolution features of the 3D object into the first data group;
putting data representing the high resolution features of the 3D object which are less than a predetermined length scale into the second data group;
shelling data representing the high resolution features of the 3D object which are greater than the predetermined length scale to provide shell data and bulk data; and
putting the shell data into the second data group and the bulk data into the first data group.

8. A method for fabricating a 3D object using the system of claim 1, the method comprising:
(a) illuminating, via the first optical assembly, the light-sensitive material with the first wavelength of light via the optical path to generate the first region of the 3D object via single photon photolithography;
(b) illuminating, via the second optical assembly, the light-sensitive material with the second wavelength of light via the optical path to generate the second region of the 3D object via multiphoton photolithography; and
(c) repeating steps (a) and (b) until the 3D object is complete.

9. The method of claim 8, wherein the 3D object is a multiscale 3D object.

10. The method of claim 8, wherein the second wavelength of light is selected to induce a two photon process in the light sensitive composition.

11. The method of claim 8, wherein the first region is within a first layer of the 3D object and the second region is also within the first layer.

12. A controller for controlling the operations of a multiscale multiphoton photolithography system, the controller comprising:
a processor; and
a non-transitory computer-readable medium operably coupled to the processor, the computer-readable medium comprising instructions that, when executed by the processor, perform operations comprising:
(a) illuminating, via a first optical assembly of the system, a light-sensitive material from which a 3D object is to be fabricated with a first wavelength of light selected to induce a single photon process in the light-sensitive composition to generate a first region of the 3D object via single photon photolithography;
(b) illuminating, via a second optical assembly of the system, the light-sensitive material with a second wavelength of light selected to induce a multiphoton process in the light-sensitive composition to generate a second region of the 3D object via multiphoton photolithography; and
(c) repeating steps (a) and (b) until the 3D object is complete.

13. The controller of claim 12, wherein the step of illuminating with the first wavelength of light occurs according to a first image pattern from single photon photolithography data received by the processor, the single photon photolithography data comprising a set of image patterns and associated layer values, wherein the first image pattern is one of the set,
and wherein the step of illuminating with the second wavelength of light occurs according to a first write sequence from multiphoton photolithography data received by the processor, the multiphoton photography data comprising a set of write sequences and associated layer values, wherein the first write sequence is one of the set.

14. The controller of claim 13, the non-transitory computer-readable medium further comprising instructions that, when executed by the processor, cause the controller to generate the single photon photolithography data and the multiphoton photolithography data.

15. The controller of claim 14, the non-transitory computer-readable medium further comprising instructions that, when executed by the processor, cause the controller to generate the single photon photolithography data and the multiphoton photolithography data by operations comprising:
partitioning a CAD file comprising data representing the 3D object to be fabricated into a first data group comprising data representing low resolution features of the 3D object and a second data group comprising data representing high resolution features of the 3D object;
slicing the first data group along a z-axis of the 3D object to provide a first plurality of layers and slicing the second data group along the z-axis to provide a second plurality of layers;
converting each layer of the first plurality of layers to an image pattern, thereby providing the single photon photolithography data comprising the set of image patterns and associated layer values and converting each layer of the second plurality of layers to a write sequence, thereby providing the multiphoton photolithography data comprising the set of write sequences and associated layer values; and
outputting the single photon photolithography data to the first optical assembly and outputting the multiphoton photolithography data to the second optical assembly.

16. The controller of claim 15, the non-transitory computer-readable medium further comprising instructions that, when executed by the processor, cause the controller to partition the CAD file by operations comprising:
putting data representing the low resolution features of the 3D object into the first data group;
putting data representing the high resolution features of the 3D object which are less than a predetermined length scale into the second data group;
shelling data representing the high resolution features of the 3D object which are greater than the predetermined length scale to provide shell data and bulk data; and
putting the shell data into the second data group and the bulk data into the first data group.

17. A non-transitory computer-readable medium comprising computer-readable instructions therein that, when executed by a processor, cause a controller configured to control the operations of a multiscale multiphoton photolithography system to:
(a) illuminate, via a first optical assembly of the system, a light-sensitive material from which a 3D object is to be fabricated with a first wavelength of light selected to induce a single photon process in the light-sensitive composition to generate a first region of the 3D object via single photon photolithography;
(b) illuminate, via a second optical assembly of the system, the light-sensitive material with a second wavelength of light selected to induce a multiphoton process in the light-sensitive composition to generate a second region of the 3D object via multiphoton photolithography; and
(c) repeat steps (a) and (b) until the 3D object is complete.

18. The computer-readable medium of claim 17, wherein the step of illuminating with the first wavelength of light occurs according to a first image pattern from single photon photolithography data received by the processor, the single photon photolithography data comprising a set of image patterns and associated layer values, wherein the first image pattern is one of the set,
and wherein the step of illuminating with the second wavelength of light occurs according to a first write sequence from multiphoton photolithography data received by the processor, the multiphoton photography data comprising a set of write sequences and associated layer values, wherein the first write sequence is one of the set.

19. The computer-readable medium of claim 18, the non-transitory computer-readable medium further comprising instructions that, when executed by the processor, cause the controller to generate the single photon photolithography data and the multiphoton photolithography data.

20. The computer-readable medium of claim 19, the non-transitory computer-readable medium further comprising instructions that, when executed by the processor, cause the controller to generate the single photon photolithography data and the multiphoton photolithography data by operations comprising:
partitioning a CAD file comprising data representing the 3D object to be fabricated into a first data group comprising data representing low resolution features of the 3D object and a second data group comprising data representing high resolution features of the 3D object;
slicing the first data group along a z-axis of the 3D object to provide a first plurality of layers and slicing the second data group along the z-axis to provide a second plurality of layers;
converting each layer of the first plurality of layers to an image pattern, thereby providing the single photon photolithography data comprising the set of image patterns and associated layer values and converting each layer of the second plurality of layers to a write sequence, thereby providing the multiphoton photolithography data comprising the set of write sequences and associated layer values; and
outputting the single photon photolithography data to the first optical assembly and outputting the multiphoton photolithography data to the second optical assembly.

21. The computer-readable medium of claim 20, the non-transitory computer-readable medium further comprising instructions that, when executed by the processor, cause the controller to partition the CAD file by operations comprising:
putting data representing the low resolution features of the 3D object into the first data group;
putting data representing the high resolution features of the 3D object which are less than a predetermined length scale into the second data group;
shelling data representing the high resolution features of the 3D object which are greater than the predetermined length scale to provide shell data and bulk data; and
putting the shell data into the second data group and the bulk data into the first data group.

22. A method for fabricating a 3D object, the method comprising:
(a) illuminating, via a first optical assembly, a light-sensitive material from which the 3D object is to be fabricated with a first wavelength of light selected to induce a single photon process in the light-sensitive composition to generate a first region of the 3D object via single photon photolithography;
(b) illuminating, via a second optical assembly, the light-sensitive material with a second wavelength of light selected to induce a multiphoton process in the light-sensitive composition to generate a second region of the 3D object via multiphoton photolithography, wherein the illuminating steps (a) and (b) occur along the same optical path of a multiscale multiphoton photolithography system; and
(c) repeating steps (a) and (b) until the 3D object is complete.
